(19) United States
(12) Patent Application Publication
(10) Pub. No.: US 2024/0381627 A1
(43) Pub. Date: Nov. 14, 2024

(54) SEMICONDUCTOR DEVICE

(71) Applicant: Samsung Electronics Co., Ltd., Suwon-si (KR)

(72) Inventors: Musarrat Hasan, Suwon-si (KR); Byounghoon Lee, Suwon-si (KR); Sukhoon Kim, Suwon-si (KR); Eulji Jeong, Suwon-si (KR)

(21) Appl. No.: 18/419,907

(22) Filed: Jan. 23, 2024

(30) Foreign Application Priority Data
May 11, 2023 (KR) 10-2023-0060995

(51) Int. Cl. H10B 12/00

(52) U.S. Cl. CPC H10B 12/50; H10B 12/315; H10B 12/34

(57) ABSTRACT

A semiconductor device includes a substrate including an NMOS region and a PMOS region, a first gate electrode inside the substrate in the NMOS region, and a second gate electrode inside the substrate in the PMOS region. The first gate electrode includes a first electrode pattern, and the second gate electrode includes a second electrode pattern. The first gate electrode further includes a first N-type conductive pattern between the first electrode pattern and the substrate. The second gate electrode further includes a P-type conductive pattern between the second electrode pattern and the substrate, and the P-type conductive pattern includes molybdenum titanium nitride (MoTiN) or molybdenum silicon nitride (MoSiN).

### CROSS-REFERENCE TO RELATED APPLICATION(S)

This U.S. non-provisional patent application claims priority under 35 U.S.C. § 119 to Korean Patent Application No. 10-2023-0060995, filed on May 11, 2023, in the Korean Intellectual Property Office, the entire contents of which are hereby incorporated by reference.

### BACKGROUND

The present disclosure relates to a semiconductor device.

A semiconductor device often includes a plurality of transistors. The transistors integrated in a semiconductor device may be formed in various structures depending on required performance such as an operating voltage and/or a driving current. For example, there is a complementary metal-oxide-semiconductor (CMOS) device structure in which an n-channel metal-oxide-semiconductor (NMOS) device and a p-channel metal-oxide-semiconductor (PMOS) device have metal gate electrodes of different conductivity types.

### SUMMARY

An object of the present disclosure is to provide a semiconductor device with improved reliability.

A semiconductor device according to some embodiments of the present disclosure includes a substrate including an NMOS region and a PMOS region, a first gate electrode inside the substrate in the NMOS region, and a second gate electrode inside the substrate in the PMOS region, wherein the first gate electrode includes a first electrode pattern, the second gate electrode includes a second electrode pattern, the first gate electrode further includes a first N-type conductive pattern between the first electrode pattern and the substrate, the second gate electrode further includes a P-type conductive pattern between the second electrode pattern and the substrate, and the P-type conductive pattern includes molybdenum titanium nitride (MoTiN) or molybdenum silicon nitride (MoSiN).

A semiconductor device according to some embodiments of the present disclosure includes a substrate including an NMOS region and a PMOS region, including a first groove formed on the substrate in the NMOS region and a second groove formed on the substrate in the PMOS region, a first gate insulating layer and a first N-type conductive pattern sequentially conformally covering an inner wall of the first groove, a first electrode pattern filling the first groove, a second gate insulating layer, a P-type conductive pattern, and a second N-type conductive pattern sequentially conformally covering an inner wall of the second groove and a second electrode pattern filling the second groove, wherein the P-type conductive pattern has a work function of 5.0 electron-volts (eV) to 5.5 eV and the P-type conductive pattern includes titanium or silicon, and a content of the titanium or the silicon is about 1.0 to 50.0 atomic percent (at. %).

A semiconductor device according to some embodiments of the present disclosure includes a substrate including a cell region and a peripheral region, the peripheral region including an NMOS region and a PMOS region, and including a cell groove formed on the substrate in the cell region, a first groove formed on the substrate in the NMOS region, and a second groove formed on the substrate in the PMOS region, a word line disposed in the cell groove, a first impurity region disposed in the substrate at one side of the word line, a second impurity region disposed in the substrate on the other side of the word line, a bit line connected to the first impurity region and crossing over the word line, a storage node contact connected to the second impurity region, a data storage pattern on the storage node contact, a first gate insulating layer and a first N-type conductive pattern sequentially conformally covering an inner wall of the first groove, a first electrode pattern filling the first groove, a second gate insulating layer, a P-type conductive pattern, and a second N-type conductive pattern sequentially conformally covering an inner wall of the second groove, and a second electrode pattern PI filling the second groove, wherein the P-type conductive pattern includes molybdenum titanium nitride (MoTiN) or molybdenum silicon nitride (MoSiN), and a content of titanium or silicon in the P-type conductive pattern is about 1.0 to 50.0 at. %.

### BRIEF DESCRIPTION OF THE DRAWINGS

Example embodiments will be more clearly understood from the following brief description taken in conjunction with the accompanying drawings, in which the same or similar elements will be denoted by the same reference labels throughout the specification and the drawings. The accompanying drawings represent non-limiting, example embodiments as described herein.

FIG. 1 illustrates a plan view of a semiconductor device according to embodiments of the present invention.

FIG. 2 illustrates cross-sectional views of the illustrative semiconductor device shown in FIG. 1 taken along lines A-A′, B-B′, C-C′, and D-D′.

FIGS. 3A and 3B illustrate cross-sectional views of a semiconductor device according to embodiments of the present invention.

FIGS. 4A to 4G are cross-sectional views illustrating intermediate processes in an example method of manufacturing the illustrative semiconductor device of FIG. 3A.

FIG. 5 are cross-sectional views of a semiconductor device according to embodiments of the present invention.

FIG. 6 are cross-sectional views of a semiconductor device according to embodiments of the present invention.

FIG. 7 are cross-sectional views of a semiconductor device according to embodiments of the present invention.

FIG. 8 are cross-sectional views of a semiconductor device according to embodiments of the present invention.

FIG. 9 are cross-sectional views of a semiconductor device according to embodiments of the present invention.

FIG. 10 are cross-sectional views of a semiconductor device according to embodiments of the present invention.

FIG. 11 are cross-sectional views of a semiconductor device according to embodiments of the present invention.

### DETAILED DESCRIPTION

Hereinafter, to explain the present disclosure in more detail, embodiments according to the present disclosure will be described with reference to the accompanying drawings.

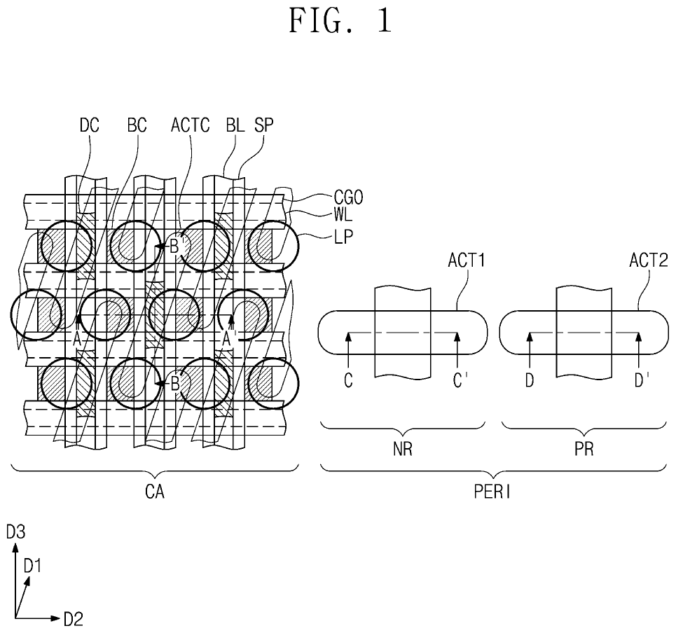

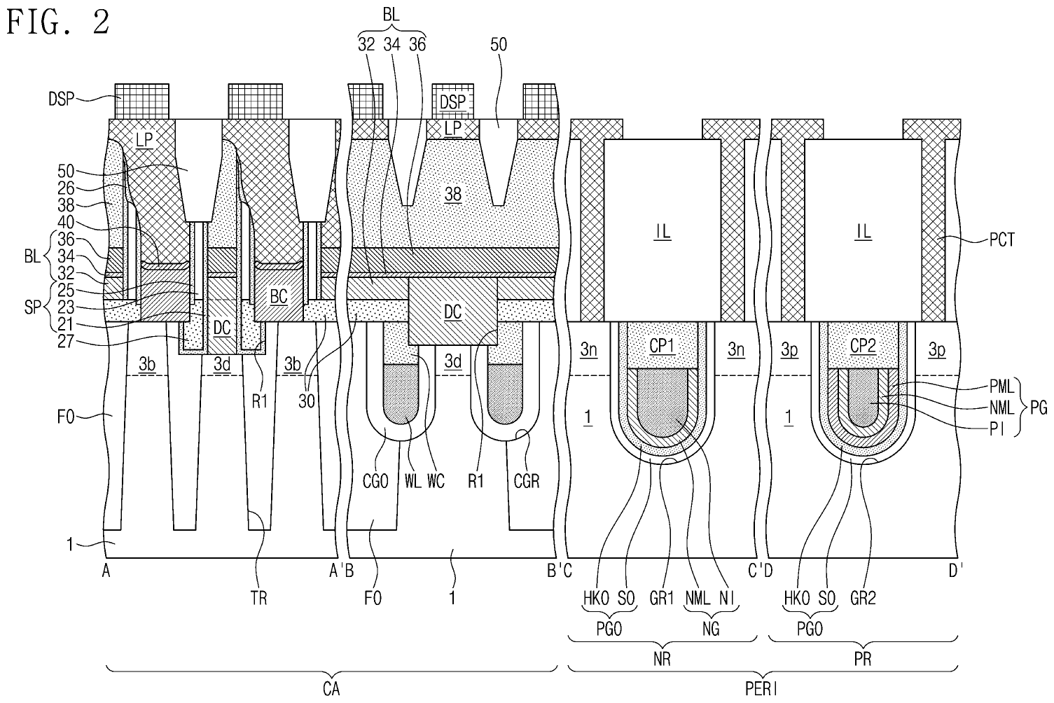

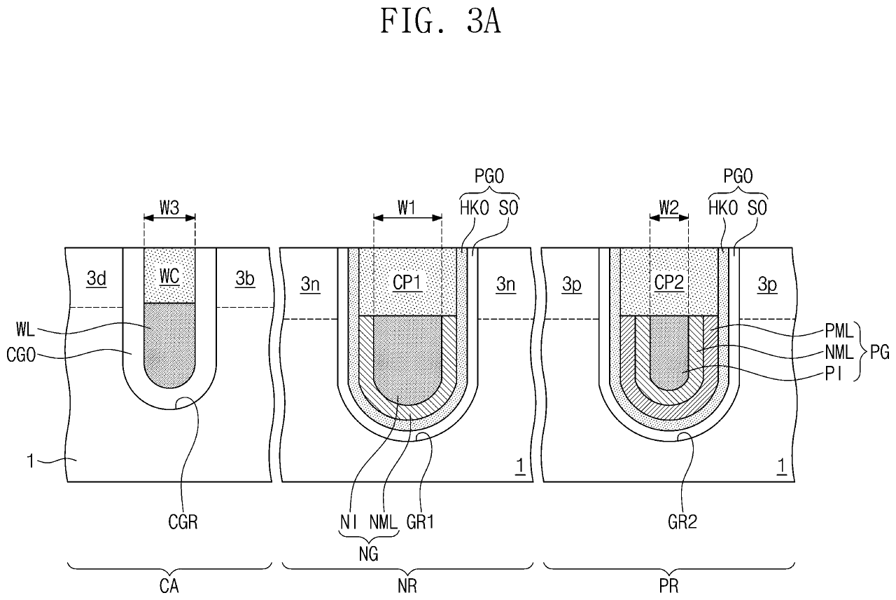

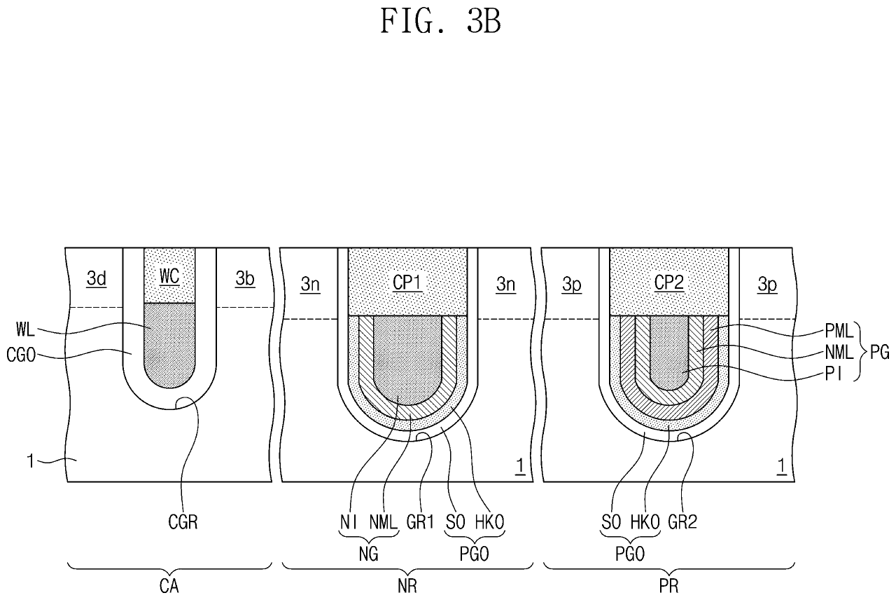

FIG. 1 illustrates a top plan view of a semiconductor device according to embodiments of the present disclosure. FIG. 2 illustrates cross-sectional views of the illustrative semiconductor device shown in FIG. 1 taken along lines A-A′, B-B′, C-C′, and D-D′. FIGS. 3A and 3B illustrate cross-sectional views of a semiconductor device according to embodiments of the present disclosure.

Referring to FIGS. 1, 2, 3A and 3B, a substrate 1 is provided. The substrate 1 may include a cell region CA and a peripheral region PERI laterally adjacent to the cell region CA (in a second direction D2). The peripheral region PERI may include an n-channel metal-oxide-semiconductor (NMOS) region NR and a p-channel metal-oxide-semiconductor (PMOS) region PR. The peripheral region PERI may be a core region and/or a peripheral circuit region. Various circuits such as a sub-word line driver, a sense amplifier, a row decoder, and a column decoder may be disposed in the peripheral region PERI.

The substrate 1 may be, for example, a silicon single crystal substrate or a silicon-on-insulator (SOI) substrate. A device isolation layer FO may be disposed on the substrate 1 to define active portions ACTC, ACT1, and ACT2. Each of the active portions ACTC, ACT1, and ACT2 may have an isolated shape, and may be spaced laterally (i.e., horizontally) from each in a third direction D3 and/or the second direction D2 (i.e., parallel to an upper surface of the substrate 1). The active portions ACTC, ACT1, and ACT2 may include cell active portions ACTC disposed in the cell region CA, a first active portion ACT1 disposed in the NMOS region NR, and a second active portion ACT2 disposed in the PMOS region PR.

Each of the cell active portions ACTC may have a bar shape that is planarly elongated in a first direction D1. When viewed in a plan view (see FIG. 1), the cell active portions ACTC may respectively correspond to portions of the substrate 1 surrounded by the device isolation layer FO. The term “surrounded” (or “surrounding,” “surrounds,” or like terms) as may be used herein is intended to broadly refer to an element, structure or layer that extends around, envelops, encircles, or encloses another element, structure or layer on all sides, although breaks or gaps may also be present. Thus, for example, a material layer having voids therein may still “surround” another layer which it encircles. The cell active portions ACTC may be arranged parallel to each other in the first direction D1, and an end of one cell active portion ACTC may be arranged adjacent to a center of the other cell active portions ACTC adjacent thereto. The device isolation layer FO may include oxide (e.g., silicon oxide), nitride (e.g., silicon nitride), and/or oxynitride (e.g., silicon oxynitride). The device isolation layer FO may be disposed in a trench TR formed in the substrate 1.

Grooves CGR, GR1, and GR2 may be formed in the substrate 1 and the device isolation layer FO. The grooves CGR, GR1, and GR2 may include cell grooves CGR disposed in the cell region CA, a first groove GR1 disposed in the NMOS region NR, and a second groove GR2 disposed in the PMOS region PR.

The cell grooves CGR may extend in the second direction D2 and may be spaced apart from each other in the third direction D3 crossing the first and second directions D1 and D2 simultaneously. Bottom surfaces of the cell grooves CGR may have a concavo-convex structure (i.e., concave on one side and convex on the opposite side).

A cell gate insulating layer CGO is disposed in each of the cell grooves CGR. The cell gate insulating layer CGO may include silicon oxide. The cell gate insulating layer CGO may conformally cover inner wall and bottom surfaces of the cell grooves CGR. The term “cover” (or “covers” or “covering,” or like terms) as may be used herein is intended to broadly refer to a material, layer or structure being on or over another material, layer or structure, but does not require the material, layer or structure to entirely cover the other material, layer or structure. The term “conformal” (or “conformally,” or like terms), as may be used herein in the context of a material layer or coating, is intended to refer broadly to a material layer or coating having a substantially uniform cross-sectional thickness relative to the contour of a surface to which the material layer is applied. At bottoms of the cell grooves CGR, the cell gate insulating layer CGO may have a concavo-convex structure.

A word line WL is disposed in each of the cell grooves CGR. Bottom surfaces of the word lines WL may be curved. A lower surface of the word line WL on the device isolation layer FO may be lower than a lower surface of the word line WL on the cell active portion ACTC. The word line WL may have a single-layer or multi-layer structure of at least one of impurity-doped polysilicon, TiN, Mo, W, Cu, Al, TaN, Ru, and Ir.

A first impurity region 3d may be disposed in each of the cell active portions ACTC between a pair of word lines WL, and a pair of second impurity regions 3d may be disposed in both edge regions of each of the cell active portions ACTC. The first and second impurity regions 3d and 3b may be doped with, for example, N-type impurities. The first impurity region 3d may correspond to a common drain region and the second impurity region 3b may correspond to a source region. Each of the word lines WL and the first and second impurity regions 3d and 3b adjacent thereto may constitute a transistor.

The word lines WL may be disposed in the cell grooves CGR, and thus a channel length of a channel region under the word lines WL may be increased within a limited plane area. Therefore, a short-channel effect and the like may be minimized.

Upper surfaces of the word lines WL may be lower, relative to an upper surface of the substrate 1, than upper surfaces of the cell active portions ACTC. A word line capping pattern WC may be disposed on each of the word lines WL. The word line capping patterns WC may have a line shape extending in a length direction of the word lines WL (i.e., in the second direction D2), and may cover the entire upper surface of the word lines WL. The word line capping patterns WC may fill the cell grooves CGR on the word lines WL. The term “fill” (or “filling,” “filled,” or like terms) as may be used herein is intended to refer broadly to either completely filling a defined space (e.g., cell grooves CGR) or partially filling the defined space; that is, the defined space need not be entirely filled but may, for example, be partially filled or have voids or other spaces throughout. The word line capping pattern WC may be formed of, for example, a silicon nitride layer.

An interlayer insulating pattern 30 may be disposed on the substrate 1. The interlayer insulating pattern 30 may be formed of at least one single layer or multiple layers selected from a silicon oxide layer, a silicon nitride layer, and a silicon oxynitride layer. The interlayer insulating patterns 30 may be formed in a form of islands spaced apart from each other on a plane. Alternatively, the interlayer insulating pattern 30 may be formed in a planar mesh shape. Upper portions of the interlayer insulating pattern 30, the substrate 1, the device isolation layer FO, and the word line capping pattern WC may be partially recessed to form a first recess region R1.

Bit lines BL may be disposed on the interlayer insulating pattern 30. The bit lines BL may cross over (i.e., intersect) the word line capping patterns WC and word lines WL. As illustrated in FIG. 1, the bit lines BL may be parallel to the third direction D3 crossing the first and second directions D1 and D2.

The bit line BL may include a bit line polysilicon pattern 32, a bit line diffusion barrier pattern 34, and a bit line wiring pattern 36 sequentially stacked in a vertical direction perpendicular to the upper surface of the substrate 1. The bit line polysilicon pattern 32 may include polysilicon doped with impurities. The bit line diffusion barrier pattern 34 may include at least one of titanium, titanium nitride (TiN), titanium silicon nitride (TiSiN), tantalum, tantalum nitride, and tungsten nitride. The bit line wiring pattern 36 may include, for example, a metal such as tungsten, aluminum, or copper. A bit line capping pattern 38 may be disposed on each of the bit lines BL. The bit line capping patterns 38 may be formed of an insulating material such as silicon nitride, although embodiments are not limited thereto.

Bit line contacts DC may be disposed in the first recess region R1 crossing the bit lines BL. The bit line contacts DC may include polysilicon doped or undoped with impurities. In the cross section B-B′ of FIG. 2, one sidewall of the bit line contact DC may be in contact with a sidewall of the interlayer insulating pattern 30. Referring to the plan view of FIG. 1, some of side surfaces of the bit line contact DC may be concave. The bit line contact DC may electrically connect the first impurity region 3d to the bit line BL.

A lower buried insulating pattern 27 may be disposed in the first recess region R1 where the bit line contact DC is not disposed. The lower buried insulating pattern 27 may be formed of at least one single layer or multiple layers selected from a group including a silicon oxide layer, a silicon nitride layer, and/or a silicon oxynitride layer.

Storage node contacts BC may be disposed between an adjacent pair of the bit lines BL. The storage node contacts BC may be spaced apart from each other. The storage node contacts BC may include polysilicon doped or undoped with impurities. Upper surfaces of the storage node contacts BC may be concave.

An insulation fence (not explicitly illustrated) may be disposed between the storage node contacts BC disposed between the bit lines BL in the third direction D3. The insulation fence may be formed of, for example, an insulating layer such as a silicon nitride layer, a silicon oxide layer, or a silicon oxynitride layer.

A bit line spacer SP may be interposed between the bit line BL and the storage node contact BC in the second direction D2. The bit line spacer SP may also cover a sidewall of the bit line capping pattern 38. The bit line spacer SP may include first to third spacers 21, 23, and 25 sequentially disposed from the sidewall of the bit line BL. The first and third spacers 21 and 25 may include a material having etching selectivity with the second spacer 23. For example, the first and third spacers 21 and 25 may include silicon nitride. The second spacer 23 may include silicon oxide. Alternatively, the second spacer 23 may be an air gap region between the first and third spacers 21 and 25, respectively.

The first spacer 21 may extend downward (i.e., vertically; perpendicular to the upper surface of the substrate 1) to cover a sidewall of the bit line contact DC. The first spacer 21 may be interposed between the lower buried insulating pattern 27 and the device isolation layer FO. In the cross section A-A of FIG. 2, an upper end of the first spacer 21 may be higher, relative to the upper surface of the substrate 1, than upper ends of the second and third spacers 23 and 25. In one or more embodiments, an upper sidewall of the first spacer 21 is not covered by the second and third spacers 23 and 25. Accordingly, a formation margin of a subsequent landing pad LP may be increased. Accordingly, it is possible to prevent a connection failure between the landing pad LP and the storage node contact BC.

An upper portion of the first spacer 21 may have a smaller cross-sectional thickness than a lower portion thereof. An upper sidewall of the first spacer 21 (i.e., extending above the second spacer 23) may be covered with a fourth spacer 26. The fourth spacer 26 may include, for example, silicon nitride. The fourth spacer 26 may serve to reinforce (at least from a structural perspective) the upper portion of the thinned first spacer 21.

A storage node ohmic layer 40 may be disposed on the upper surface of the storage node contact BC. The storage node ohmic layer 40 may include metal silicide. A landing pad LP is disposed on the storage node ohmic layer 40. Although not illustrated, a diffusion barrier may be interposed between the storage node ohmic layer 40 and the landing pad LP. The diffusion barrier may include, for example, a metal nitride. The landing pad LP may be formed of a metal-containing material such as tungsten, although embodiments are not limited thereto. An upper portion of the landing pad LP may cover an upper surface of the bit line capping pattern 38. A center of the landing pad LP may shift from a center of the storage node contact BC in the second direction D2. A portion of the bit line BL may vertically overlap the landing pad LP. The term “overlap” (or “overlapping,” or like terms), as used herein, is intended to broadly refer to a first element that intersects with at least a portion of a second element in the vertical direction (i.e., perpendicular to the upper surface of the substrate 1), but does not require that the first and second elements be completely aligned with one another in a horizontal plane (i.e., in the second direction D2 and/or third direction D3).

A landing pad separation pattern 50 may be disposed between the landing pads LP, electrically isolating adjacent landing pads LP from each other in the second direction D2 and/or third direction D3. The landing pad separation pattern 50 may have, for example, a single layer or a multilayer structure of at least one of silicon oxide, silicon nitride, silicon oxynitride, and SiOC. The landing pad separation pattern 50 may extend downward and pass through a portion of the bit line capping pattern 38 to be in contact with the second spacer 23.

A data storage portion DSP may be disposed on at least a portion of an upper surface of the landing pads LP. The data storage portion DSP may be a capacitor including a lower electrode, a dielectric layer, and an upper electrode. Alternatively, the data storage portion DSP may include a magnetic tunnel junction pattern. Alternatively, the data storage portion DSP may include a phase change material or a variable resistance material.

Inner walls of the first groove GR1 disposed in the NMOS region NR and the second groove GR2 disposed in the PMOS region PR are each conformally covered with a peripheral gate insulating layer PGO. The peripheral gate insulating layer PGO may include a silicon oxide layer SO and a high dielectric layer HKO sequentially stacked. The high dielectric layer HKO may include a material having a dielectric constant higher than that of silicon oxide. The high dielectric layer HKO may include at least one single layer or multilayer structure selected from, for example, hafnium oxide (HfO), hafnium silicate (HfSiO), hafnium oxynitride (HfON), hafnium silicon oxynitride (HfSiON), lanthanum oxide (LaO), lanthanum aluminum oxide (LaAlO), Zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), strontium titanium oxide (SrTiO), yttrium oxide (YO), aluminum oxide (AlO), or lead scandium tantalum oxide (PbScTaO).

A first gate electrode NG is disposed in the first groove GR1 in the NMOS region NR. The first gate electrode NG may include an N-type conductive pattern NML, in contact with the peripheral gate insulating layer PGO, and a first electrode pattern NI sequentially stacked. The N-type conductive pattern NML in the first groove GR1 may have a constant cross-sectional thickness regardless of the location thereof. The first electrode pattern NI may fill a lower portion of the first groove GR1.

A second gate electrode PG is disposed in the second groove GR2 in the PMOS region PR. The second gate electrode PG may include a P-type conductive pattern PML in contact with the peripheral gate insulating layer PGO, an N-type conductive pattern NML thereon, and a second electrode pattern PI thereon; that is, the P-type conductive pattern PML, the N-type conductive pattern NML, and the second electrode pattern PI are sequentially stacked. In the second groove GR2, the P-type conductive pattern PML and the N-type conductive pattern NML may each have a constant cross-sectional thickness regardless of positions thereof. The second electrode pattern PI may fill a lower portion of the second groove GR2. Each of the P-type conductive pattern PML and the N-type conductive pattern NML may have a ‘U’-shaped cross section.

The N-type conductive pattern NML may be formed of a metal-containing layer having an N-type work function. For example, the N-type conductive pattern NML may be formed of a single layer or multi-layer structure of at least one selected from lanthanum (La), lanthanum oxide (LaO), tantalum (Ta), tantalum nitride (TaN), niobium (Nb), or titanium nitride (TiN). The N-type conductive pattern NML may be formed through atomic layer deposition (ALD).

The P-type conductive pattern PML may be formed of a metal-containing layer having a P-type work function. The P-type conductive pattern PML may preferably have a work function of 5.0 eV to 5.5 eV, although embodiments are not limited thereto. The P-type conductive pattern PML may have thermal stability at 100° C. to 1200° C. The term “thermal stability” as used herein may be defined as the ability of a material to resist the action of heat energy by maintaining its mechanical properties like strength, toughness, or elasticity at a given temperature or range of temperatures.

The P-type conductive pattern PML may preferably include molybdenum (Mo) and nitrogen (N). The P-type conductive pattern PML may further include titanium or silicon. The P-type conductive pattern PML may have a single layer or multilayer structure including at least one of molybdenum titanium nitride (MoTiN), molybdenum silicon nitride (MoSiN), titanium-doped molybdenum nitride (Ti-doped MoN), and silicon-doped molybdenum nitride (Si-doped MoN). A content of the titanium or the silicon in the P-type conductive pattern PML may be about 1.0 to 50.0 at. %. The content may also be referred to as atomic concentration. The P-type conductive pattern PML may be formed through atomic layer deposition (ALD).

Each of the first electrode pattern NI and the second electrode pattern PI may have a single layer or multilayer structure of at least one of impurity-doped polysilicon, metal silicide, titanium nitride, and tungsten. The first electrode pattern NI may have a first width W1 in the second direction D2 (FIG. 3A). The second electrode pattern PI may have a second width W2 in the second direction D2 (FIG. 3A). The word line WL may have a third width W3 in the third direction D3 (FIG. 3A). The second width W2 may be smaller than the first width W1. The third width W3 may be smaller than the first width W1 or the second width W2.

A first gate capping pattern CP1 may be disposed on the first electrode pattern NI. A second gate capping pattern CP2 may be disposed on the second electrode pattern PI. The first gate capping pattern CP1 and the second gate capping pattern CP2 may be formed of silicon nitride. Upper surfaces of the first gate capping pattern CP1 and the second gate capping pattern CP2 may be coplanar with the upper surface of the substrate 1. Lower surfaces of the word line capping pattern WC, the first gate capping pattern CP1, and the second gate capping pattern CP2 may be at different levels relative to bottom surface of the substrate 1.

As illustrated in FIG. 3A, the silicon oxide layer SO and the high dielectric layer HKO of the peripheral gate insulating layer PGO may be interposed between the first gate capping pattern CP1 and the substrate 1 and between the second gate capping pattern CP2 and the substrate 1.

Alternatively, as illustrated in FIG. 3B, only the silicon oxide layer SO of the peripheral gate insulating layer PGO may be interposed between the first gate capping pattern CP1 and the substrate 1 and between the second gate capping pattern CP2 and the substrate 1; an upper end of the high dielectric layer HKO may be covered with the first gate capping pattern CP1 and the second gate capping pattern CP2. In this example, the high dielectric layer HKO may not be exposed on the upper surface of the substrate 1, and thus the possibility that the high dielectric layer HKO comes into contact with the peripheral contacts PCT (FIG. 2) may be reduced. Accordingly, leakage current or the like caused by the high dielectric layer HKO may be prevented, thereby improving reliability of the semiconductor device.

First source/drain regions 3n may be disposed in the substrate 1 at both sides of the first gate electrode NG. The first source/drain regions 3n may be doped with N-type impurities. The N-type impurity may be, for example, phosphorus or arsenic. Second source/drain regions 3p may be disposed in the substrate 1 at both sides of the second gate electrode PG. The second source/drain regions 3p may be doped with P-type impurities. The P-type impurity may be boron, for example.

The first gate electrode NG and the first source/drain regions 3n may constitute an NMOS transistor. The second gate electrode PG and the second source/drain regions 3p may constitute a PMOS transistor.

Similar to the word line WL of the cell region CA, the first gate electrode NG and the second gate electrode PG may be disposed in the substrate 1, and thus a channel length of a channel region therebelow may increase in a limited plane area. Therefore, a short-channel effect and the like may be minimized. A step between the cell region CA and the peripheral region PERI may be removed, thereby preventing process defects and simplifying an intermediate process step in a subsequent manufacturing process, such as forming the bit line BL.

Conventionally, silicon germanium has been used to adjust the work function to improve performance of a PMOS transistor, but silicon germanium is difficult to conformally form in the groove by ALD in a manufacturing process. However, in the present disclosure, molybdenum titanium nitride (MoTiN), molybdenum silicon nitride (MoSiN), titanium-doped molybdenum nitride (Ti-doped MoN) or silicon-doped molybdenum nitride (Si-doped MoN) are used as the P-type conductive pattern PML and may be used to conformally form an ALD layer in the second groove GR2. In addition, molybdenum titanium nitride (MoTiN), molybdenum silicon nitride (MoSiN), titanium-doped molybdenum nitride (Ti-doped MoN), or silicon-doped molybdenum nitride (Si-doped MoN) may have a high work function (preferably 5.0 eV to 5.5 eV) and excellent thermal stability, and when used as the P-type conductive pattern PML, a threshold voltage of the PMOS transistor may be constant even at a high temperature, thereby improving operation reliability of the semiconductor device.

The peripheral region PERI may be covered with an interlayer insulating layer IL, as shown in FIG. 2. Peripheral contacts PCT may pass through the interlayer insulating layer IL and may be in contact with the first source/drain regions 3n and the second source/drain regions 3p. The peripheral contacts PCT may be formed of the same material as the landing pad LP, although embodiments are not limited thereto. An upper surface of the interlayer insulating layer IL may be coplanar with an upper surface of the bit line capping pattern 38.

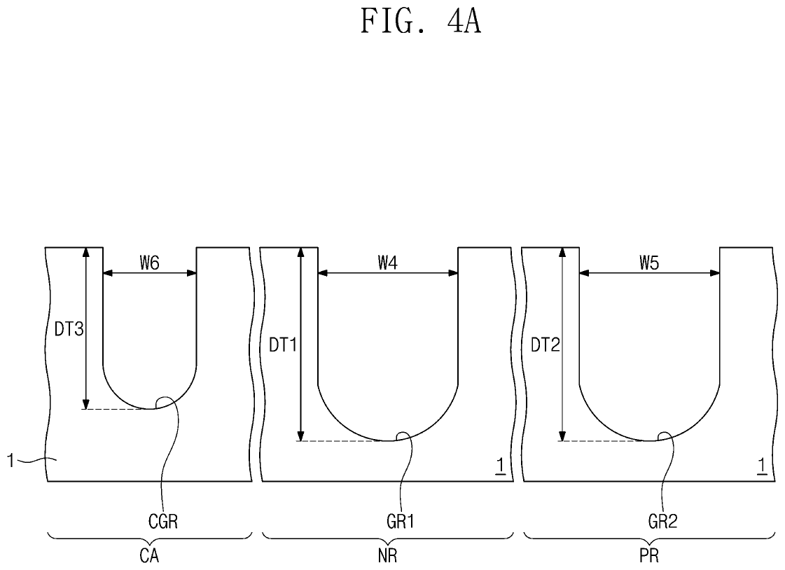

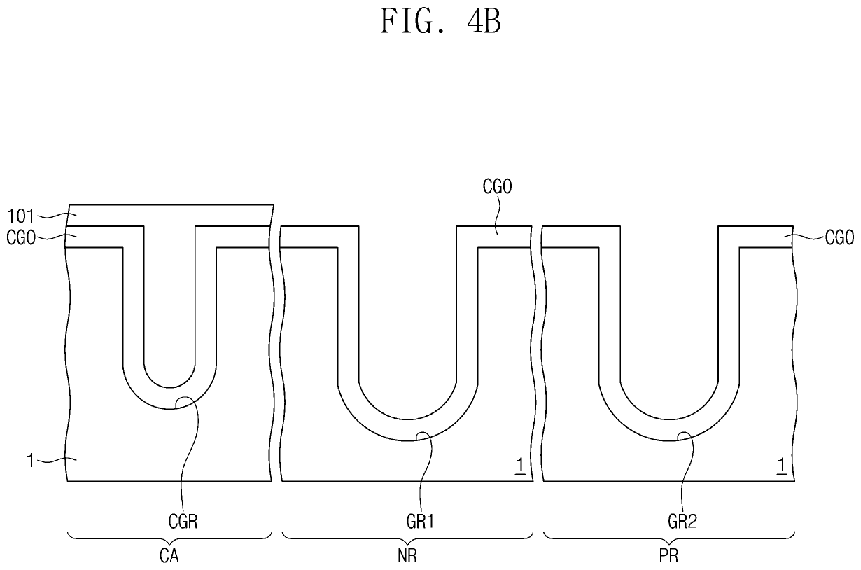

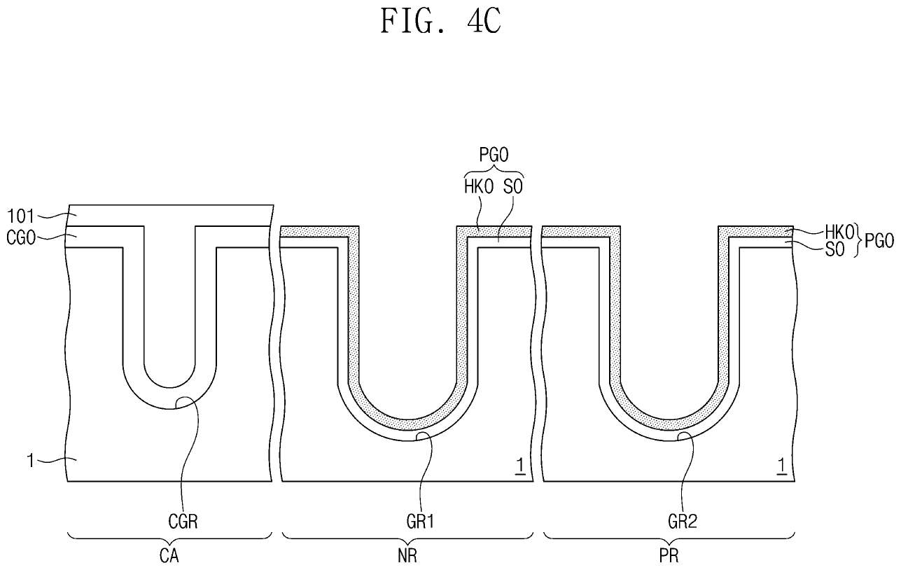

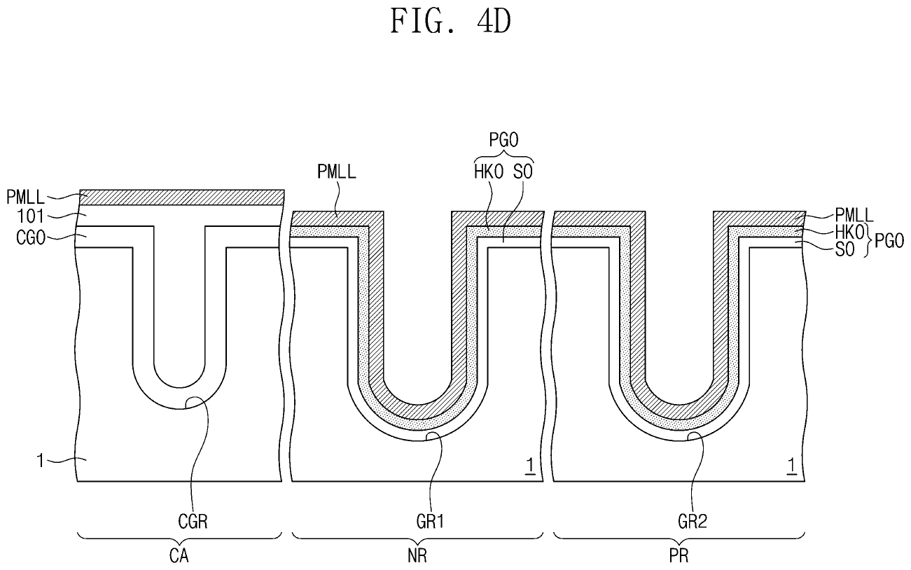

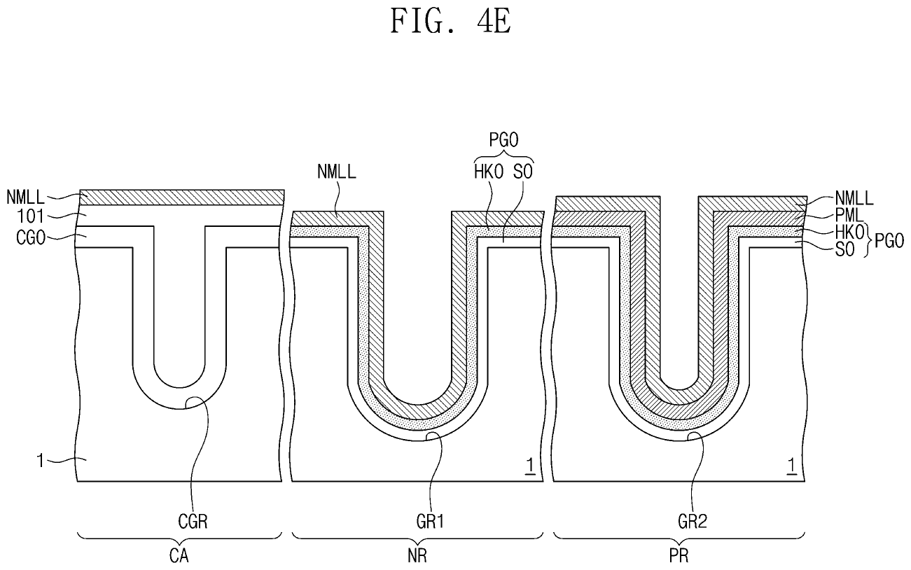

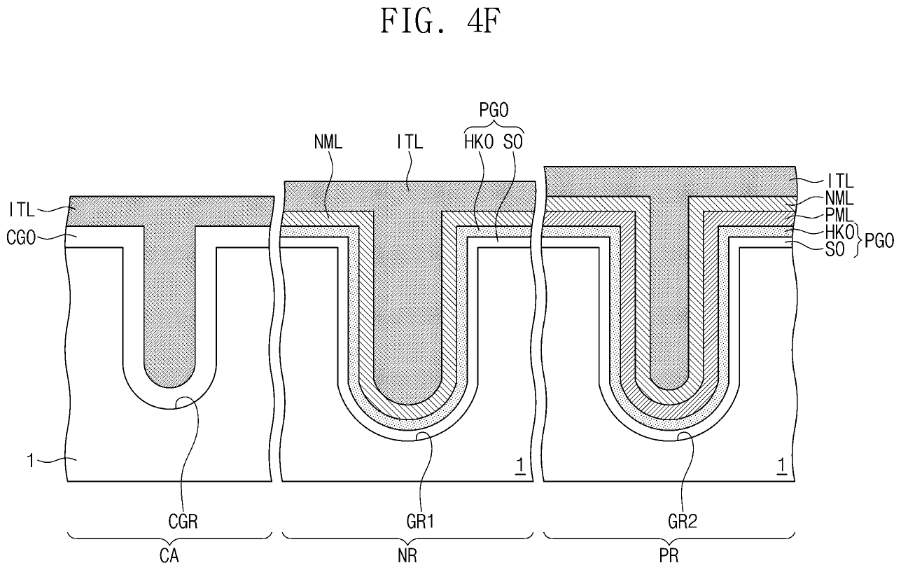

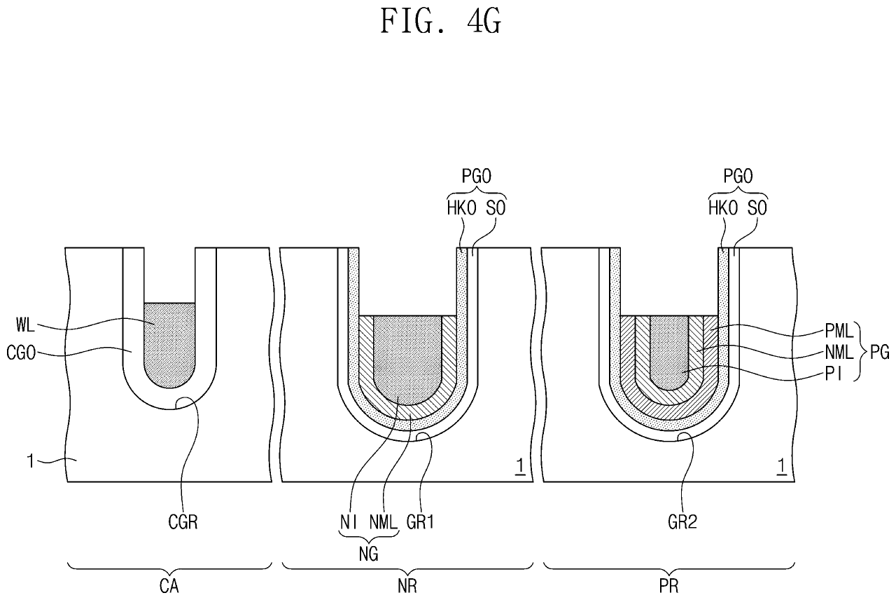

FIGS. 4A to 4G are cross-sectional views illustrating intermediate processes in an example method of manufacturing the semiconductor device of FIG. 3A.

Referring to FIG. 4A, grooves CGR, GR1 and GR2 are formed on the substrate 1. The cell groove CGR may be formed in a cell array region CA. The first groove GR1 may be formed in an NMOS region NR. The second groove GR2 may be formed in a PMOS region PR. The grooves CGR, GR1, and GR2 may have different widths and depths in the substrate 1. For example, the first groove GR1 may be formed to have a fourth width W4 and a first depth DT1. The second groove GR2 may have a fifth width W5 and a second depth DT2. The cell groove CGR may have a sixth width W6 and a third depth DT3. The sixth width W6 may be smaller than the fourth and fifth widths W4 and W5. The fourth width W4 and the fifth width W5 may be equal to each other. The third depth DT3 may be smaller than the first depth DT1 and the second depth DT2. The first depth DT1 and the second depth DT2 may be equal to each other.

Referring to FIG. 4B, a cell gate insulating layer CGO may be conformally formed on the entire surface of the substrate 1. The cell gate insulating layer CGO may be formed of, for example, silicon oxide by an atomic layer deposition (ALD) process. A protective layer 101 may be formed in the cell region CA to cover the cell gate insulating layer CGO and fill the cell groove CGR. The protective layer 101 may be formed of a material having an etching selectivity to that of the cell gate insulating layer CGO. The protective layer 101 may be formed in a single layer or multilayer structure of at least one of, for example, silicon nitride, silicon oxynitride, polysilicon, silicon germanium, spin on hardmask (SOH), amorphous carbon layer (ACL), and/or silicon carbon nitride (SiCN). The cell gate insulating layer CGO on the first groove GR1 and the second groove GR2 is exposed without being covered with the protective layer 101.

Referring to FIG. 4C, the cell gate insulating layer CGO on the first groove GR1 and the second groove GR2 is removed to expose the surface of the substrate 1. A silicon oxide layer SO and a high dielectric layer HKO are sequentially and conformally stacked on the first groove GR1 and the second groove GR2. The silicon oxide layer SO and the high dielectric layer HKO may be respectively formed by an atomic layer deposition (ALD) process. In one example, the silicon oxide layer SO may be formed as at least a part of the cell gate insulating layer CGO. That is, the high dielectric layer HKO may be formed in a state in which only a portion of the cell gate insulating layer CGO is removed, or the high dielectric layer HKO may be directly formed without removing the cell gate insulating layer CGO. The silicon oxide layer SO and the high dielectric layer HKO may form a peripheral gate insulating layer PGO.

Referring to FIG. 4D, a P-type conductive layer PMLL is conformally formed on the entire surface of the substrate 1. The P-type conductive layer PMLL is preferably formed of molybdenum titanium nitride (MoTiN), molybdenum silicon nitride (MoSiN), titanium-doped molybdenum nitride (Ti-doped MoN) or silicon-doped molybdenum nitride (Si-doped MoN). Molybdenum titanium nitride (MoTiN), molybdenum silicon nitride (MoSiN), titanium-doped molybdenum nitride (Ti-doped MoN), or silicon-doped molybdenum nitride (Si-doped MoN) are easily formed by ALD (Atomic Layer Deposition) and may be conformally formed in a concavo-convex structure in which the grooves GR1 and GR2 are formed.

In the present disclosure, molybdenum nitride (MoN) is doped with titanium or silicon as a P-type conductive layer PMLL (or titanium or silicon is added) to improve thermal stability. Accordingly, deformation of the P-type conductive pattern PML may not occur even at a high temperature during subsequent operation of the semiconductor device, and a threshold voltage of the PMOS transistor may be constant, thereby improving operational reliability. Doping molybdenum nitride (MoN) with titanium or silicon may proceed in situ when depositing molybdenum nitride (MoN) with ALD. Alternatively, titanium or silicon may be doped through an ion implantation process after forming a molybdenum nitride (MoN) layer. A content of the titanium or the silicon in the P-type conductive layer PMLL may be about 1.0 to 50.0 at. %.

Referring to FIG. 4E, an etching process is performed to remove the P-type conductive layer PMLL from the cell region CA and the NMOS region NR, and the P-type conductive layer PMLL is left only in the PMOS region PR to form a P-type conductive pattern PML. Although not illustrated, a separate mask layer covering the PMOS region PR and exposing the cell region CA and the NMOS region NR may be used in the etching process. When the P-type conductive pattern PML is formed only in the PMOS region PR, an N-type conductive layer NMLL is conformally formed on the entire surface of the substrate 1. The N-type conductive layer NMLL may be formed by ALD.

Referring to FIG. 4F, the N-type conductive layer NMLL is removed from the cell region CA, and the N-type conductive layer NMLL only remains in the PMOS region PR and the NMOS region NR, thereby forming an N-type conductive pattern NML. In addition, the protective layer 101 is removed from the cell region CA, including in the cell groove CGR, to expose the cell gate insulating layer CGO. An electrode layer ITL is deposited on the entire surface of the substrate 1, including filling the grooves CGR, GR1, and GR2.

Referring to FIG. 4G, an etch-back process is performed on the electrode layer ITL, the N-type conductive pattern NML, and the P-type conductive pattern PML to expose the upper surface of the substrate 1, and simultaneously a word line WL is formed in the cell groove CGR contacting the cell gate insulating layer CGO, a first gate electrode NG is formed in the first groove GR1 contacting the peripheral gate insulating layer PGO, and a second gate electrode PG is formed in the second groove GR2 contacting the peripheral gate insulating layer PGO. Upper surfaces of the word line WL, the first gate electrode NG, and the second gate electrode PG may be lower than the upper surface of the substrate 1. As a result, an upper sidewall of the cell gate insulating layer CGO and an upper sidewall of the peripheral gate insulating layer PGO may be exposed in the respective grooves CGR, GR1 and GR2.

Referring back to FIG. 3A, a capping layer is deposited on the entire surface of the substrate 1 and an etch-back or CMP process is performed to expose the upper surface of the substrate 1, and simultaneously a word line capping pattern WC is formed in the cell groove CGR, a first gate capping pattern CP1 is formed in the first groove GR1, and a second gate capping pattern CP2 is formed in the second groove GR2. Then, an ion implantation process is performed to form first and second impurity regions 3d and 3b in the cell region CA, first source/drain regions 3n in the NMOS region NR, and second source/drain regions 3p in the PMOS region PR of the substrate 1. As a result, the semiconductor device of FIG. 3A may be manufactured.

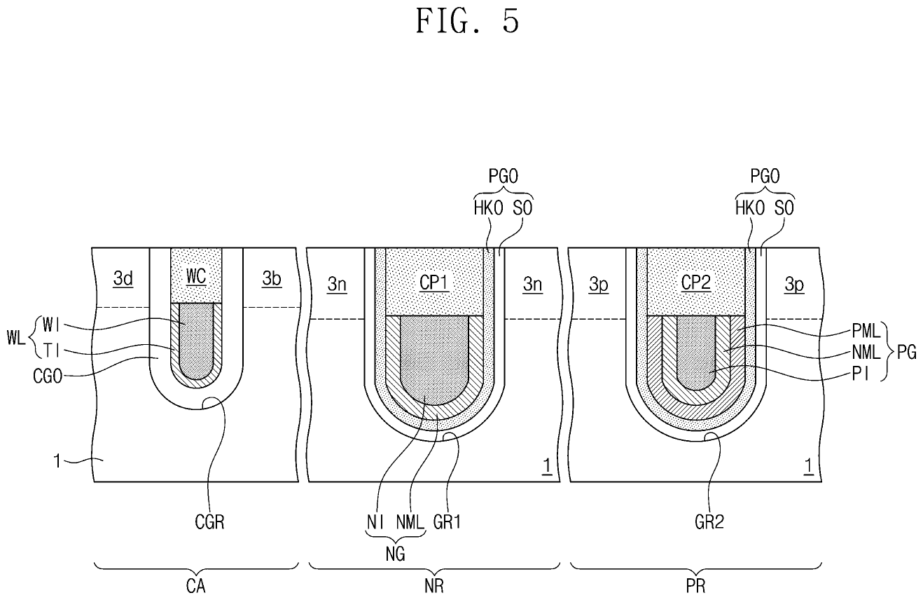

FIG. 5 are cross-sectional views of a semiconductor device according to embodiments of the present disclosure.

Referring to FIG. 5, in a semiconductor device according to the present embodiment, a word line WL may include a first cell electrode (i.e., conductive) pattern TI and a second cell electrode pattern WI in the cell groove CGR in the substrate 1. The first cell electrode pattern TI may be in contact with the cell gate insulating layer CGO and may have a constant cross-sectional thickness regardless of the location thereof. The second cell electrode pattern WI may fill a lower portion of the cell groove CGR. A peripheral gate insulating layer PGO and a first gate electrode NG are disposed in the first groove GR1 in the NMOS region NR. A peripheral gate insulating layer PGO and a second gate electrode PG are disposed in the second groove GR2 in the PMOS region PR. In this example, the peripheral gate insulating layer PGO, the first gate electrode NG, and the second gate electrode PG may have the same/similar structure to that described with reference to FIG. 3A or FIG. 3B. The first cell electrode pattern TI may include the same material as the N-type conductive pattern NML. The first cell electrode pattern TI may be formed simultaneously with the N-type conductive pattern NML and may have the same thickness as each other. For example, the first cell electrode pattern TI and the N-type conductive pattern NML may include titanium nitride. The second cell electrode pattern WI, the first electrode pattern NI, and the second electrode pattern PI may include the same material as each other. The second cell electrode pattern WI, the first electrode pattern NI, and the second electrode pattern PI may be formed simultaneously with each other. The second cell electrode pattern WI, the first electrode pattern NI, and the second electrode pattern PI may include, for example, polysilicon and/or tungsten doped with impurities.

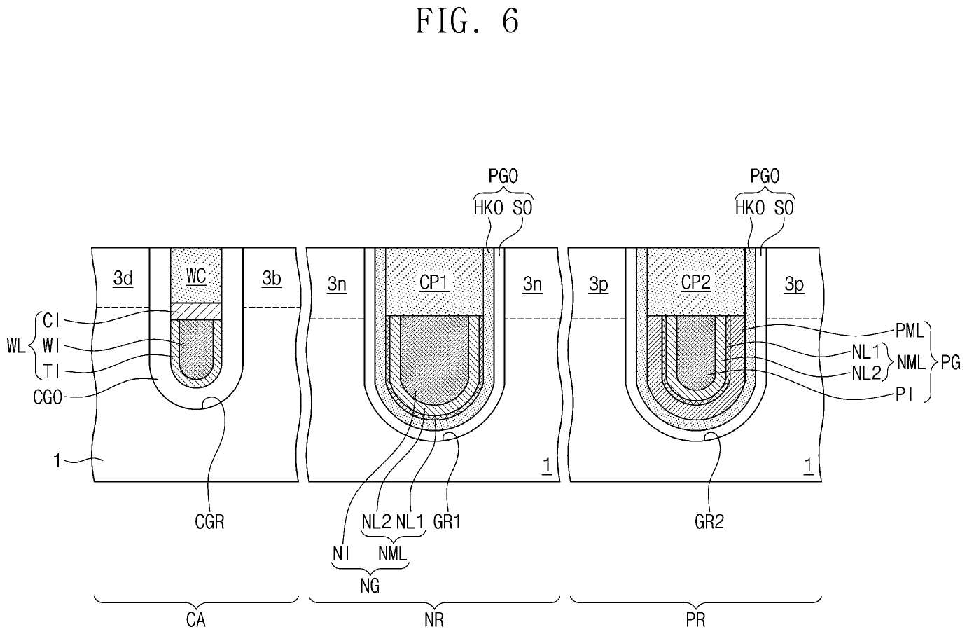

FIG. 6 are cross-sectional views of a semiconductor device according to embodiments of the present disclosure.

Referring to FIG. 6, in a semiconductor device according to the present embodiment, a word line WL may include a first cell electrode pattern TI, a second cell electrode pattern WI, and a third cell electrode pattern CI. The first cell electrode pattern TI may be in contact with the cell gate insulating layer CGO in the cell groove CGR and may have a constant cross-sectional thickness regardless of the location thereof. The second cell electrode pattern WI may be in contact with the first cell electrode pattern TI and fill a lower portion of the cell groove CGR. The third cell electrode pattern CI may be disposed on the first cell electrode pattern TI and the second cell electrode pattern WI and may be in contact with upper surfaces thereof.

A peripheral gate insulating layer PGO and a first gate electrode NG are disposed in the first groove GR1 in the NMOS region NR of the substrate 1. A peripheral gate insulating layer PGO and a second gate electrode PG are disposed in the second groove GR2 in the PMOS region PR of the substrate 1. The N-type conductive patterns NML included in the first gate electrode NG and the second gate electrode PG may include first sub-N-type conductive patterns NL1 and second sub-N-type conductive patterns NL2 sequentially stacked on the peripheral gate insulating layer PGO. The first sub-N-type conductive pattern NL1 and the second sub-N-type conductive pattern NL2 may include different materials and have different cross-sectional thicknesses, although embodiments are not limited thereto. The first sub-N type conductive pattern NL1 may preferably include lanthanum (La).

The third cell electrode pattern CI may be formed of a conductive material (referred to as a second conductive material) having a work function greater than that of a conductive material (referred to as a first conductive material) constituting the first cell electrode pattern TI and the second cell electrode pattern WI. When a word line WL is OFF (i.e., when the word line WL conveys a voltage configured to turn off or disable a corresponding memory cell(s)), an electric field around the third cell electrode pattern CI adjacent to the first and second impurity regions 3d and 3b may decrease due to a difference in the work function of the first conductive material and the second conductive material. As a result, leakage current may be reduced during OFF operation. In addition, when the word line WL is turned ON (i.e., when the word line WL conveys a voltage configured to turn on or enable a corresponding memory cell(s)), inversion around the third cell electrode pattern CI may be improved due to the work function difference, and ON current may increase. Accordingly, ON/OFF controllability of the word line WL may be improved. The first work function of the first conductive material may be, for example, 4.2 eV or less, and the second work function of the second conductive material may be, for example, 4.4 eV or more. The second sub-N type conductive pattern NL2 may include the same material as that of the first cell electrode pattern TI. For example, the first cell electrode pattern TI and the second sub-N type conductive pattern NL2 may include titanium nitride. The second cell electrode pattern WI, the first electrode pattern NI, and the second electrode pattern PI may be formed of the same material and may include, for example, tungsten. The third cell electrode pattern CI may be formed of polysilicon doped with impurities. Other structures may be the same/similar to those described above.

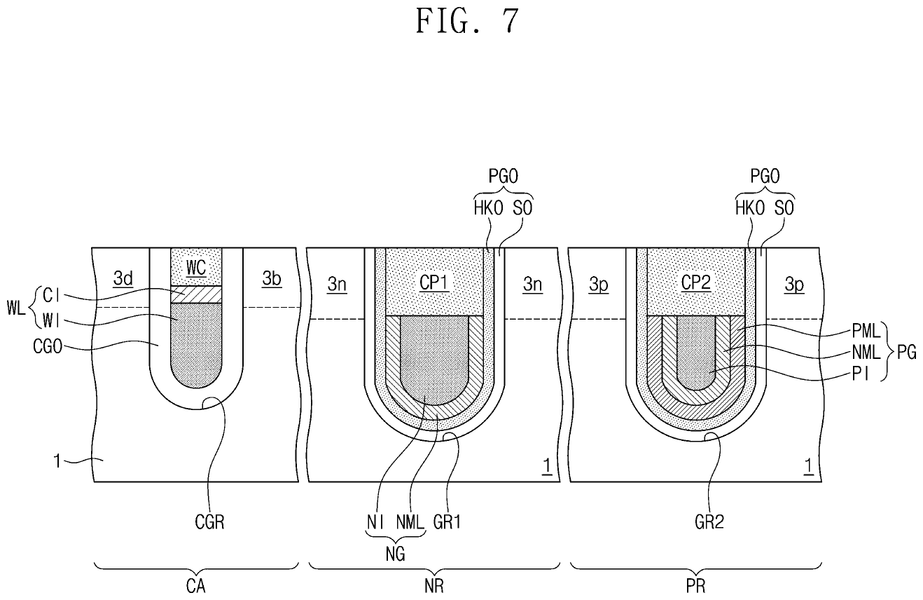

FIG. 7 are cross-sectional views of a semiconductor device according to embodiments of the present disclosure.

Referring to FIG. 7, in a semiconductor device according to the present embodiment, a word line WL may include a second cell electrode pattern WI and a third cell electrode pattern CI. The second cell electrode pattern WI may fill a lower portion of the cell groove CGR in the substrate 1. The third cell electrode pattern CI may be disposed on an upper surface of the second cell electrode pattern WI and may be in contact with the cell gate insulating layer CGO. A peripheral gate insulating layer PGO and a first gate electrode NG are disposed in the first groove GR1 in the NMOS region NR of the substrate 1. A peripheral gate insulating layer PGO and a second gate electrode PG are disposed in the second groove GR2 in the PMOS region PR of the substrate 1. The second cell electrode pattern WI may be formed of the same material as the N-type conductive pattern NML and may be formed at the same time. The second cell electrode pattern WI may be formed of a single layer of titanium nitride. Alternatively, the second cell electrode pattern WI may be formed of a single layer of tungsten. The third cell electrode pattern CI, the first electrode pattern NI, and the second electrode pattern PI may be formed of the same material, for example, polysilicon doped with impurities. Other configurations may be the same/similar to those described above.

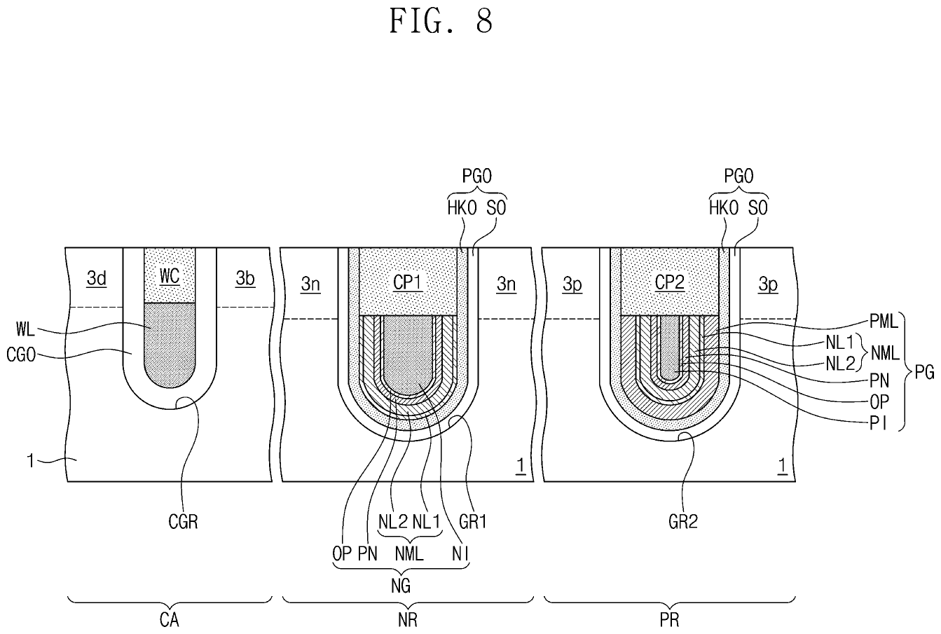

FIG. 8 are cross-sectional views of a semiconductor device according to embodiments of the present disclosure.

Referring to FIG. 8, in a semiconductor device according to the present embodiment, a word line WL may be formed of a single metal layer in the cell groove CGR in the substrate 1. A peripheral gate insulating layer PGO and a first gate electrode NG are disposed in the first groove GR1. A peripheral gate insulating layer PGO and a second gate electrode PG are disposed in the second groove GR2. The first gate electrode NG may include a polysilicon pattern PN interposed between the first electrode pattern NI and the N-type conductive pattern NML, and a metal-containing pattern OP. The second gate electrode PG may include a polysilicon pattern PN interposed between the second electrode pattern PI and the N-type conductive pattern NML, and a metal-containing pattern OP. The polysilicon pattern PN may be in contact with the N-type conductive pattern NML and may have a ‘U’-shaped cross section. The polysilicon pattern PN may be doped with N-type or P-type impurities. The metal-containing pattern OP is disposed on the polysilicon pattern PN. The metal-containing pattern OP may be formed of metal silicide, metal nitride, or metal silicon nitride. The word line WL may be formed of the same material as the first electrode pattern NI and the second electrode pattern PI and may be formed at the same time. The word line WL, the first electrode pattern NI, and the second electrode pattern PI may be formed of, for example, a single layer of tungsten. Other configurations may be the same/similar to those described above.

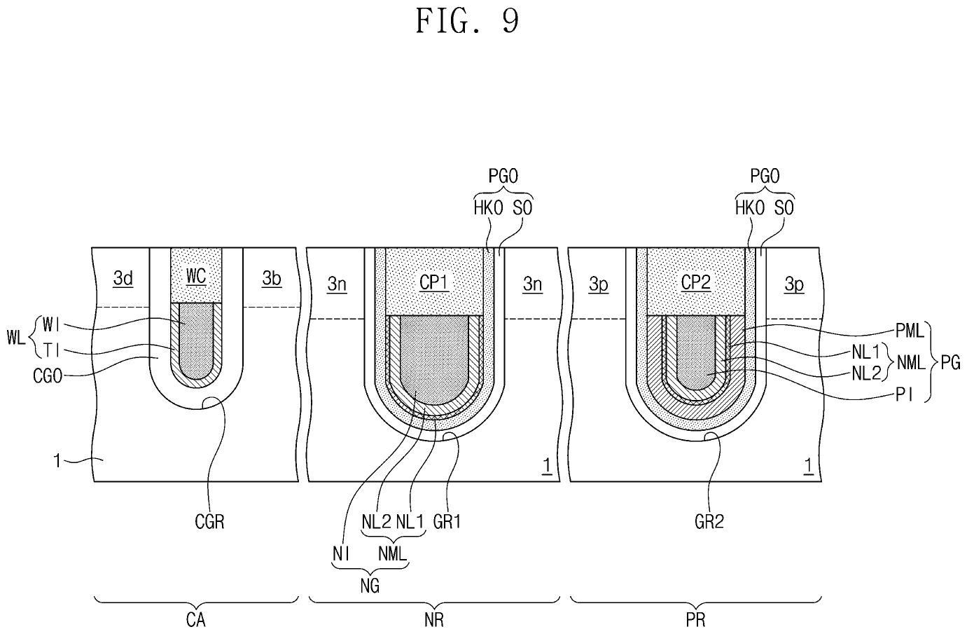

FIG. 9 is cross-sectional views of a semiconductor device according to embodiments of the present disclosure.

Referring to FIG. 9, in a semiconductor device according to the present embodiment, a word line WL may include a first cell electrode pattern TI and a second cell electrode pattern WI. A peripheral gate insulating layer PGO and a first gate electrode NG are disposed in the first groove GR1. A peripheral gate insulating layer PGO and a second gate electrode PG are disposed in the second groove GR2. The N-type conductive patterns NML included in the first gate electrode NG and the second gate electrode PG may include a first sub-N-type conductive pattern NL1 and a second sub-N-type conductive pattern NL2 sequentially stacked on the peripheral gate insulating layer PGO. The first sub-N-type conductive pattern NL1 and the second sub-N-type conductive pattern NL2 may include different materials and have different thicknesses. The first sub-N type conductive pattern NL1 may preferably include lanthanum (La). The second sub-N type conductive pattern NL2 may include the same material as the first cell electrode pattern TI. For example, the first cell electrode pattern TI and the second sub-N type conductive pattern NL2 may include titanium nitride. The second cell electrode pattern WI, the first electrode pattern NI, and the second electrode pattern PI are formed of the same material and may include, for example, tungsten. Other structures may be the same/similar to those described above.

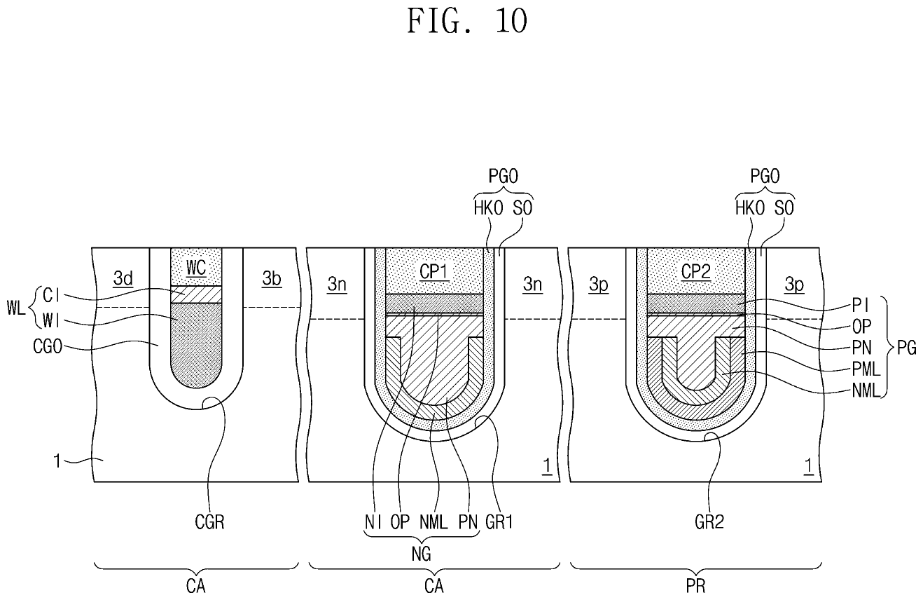

FIG. 10 is cross-sectional views of a semiconductor device according to embodiments of the present disclosure.

Referring to FIG. 10, in a semiconductor device according to the present embodiment, a word line WL may include a second cell electrode pattern WI and a third cell electrode pattern CI. The second cell electrode pattern WI may fill a lower portion of the cell groove CGR. The third cell electrode pattern CI may be disposed on the second cell electrode pattern WI and may be in contact with the cell gate insulating layer CGO. A peripheral gate insulating layer PGO and a first gate electrode NG are disposed in the first groove GR1. A peripheral gate insulating layer PGO and a second gate electrode PG are disposed in the second groove GR2. The first gate electrode NG includes an N-type conductive pattern NML, a polysilicon pattern PN, a metal-containing pattern OP, and a first electrode pattern NI that are sequentially stacked. The second gate electrode PG includes a P-type conductive pattern PML, an N-type conductive pattern NML, a polysilicon pattern PN, a metal-containing pattern OP, and a second electrode pattern PI that are sequentially stacked. The P-type conductive pattern PML and the N-type conductive pattern NML may have a ‘U’-shaped cross section. A portion of the polysilicon pattern PN may be inserted into the N-type conductive pattern NML, and another portion thereof may protrude out of the N-type conductive pattern NML to cover an upper end of the N-type conductive pattern NML. In the second gate electrode PG, a portion of the polysilicon pattern PN may cover an upper end of the P-type conductive pattern PML. Lower surfaces of the metal-containing pattern OP, first electrode pattern NI, and second electrode pattern PI are higher than upper surfaces of the P-type conductive pattern PML and the N-type conductive pattern NML. The polysilicon pattern PN may be formed of the same material as the third cell electrode pattern CI. The polysilicon pattern PN may be doped with N-type or P-type impurities. The metal-containing pattern OP is disposed on the polysilicon pattern PN. The metal-containing pattern OP may be formed of metal silicide, metal nitride, or metal silicon nitride. The word line WL may be formed of the same material as the first electrode pattern NI and the second electrode pattern PI and may be formed at the same time. The word line WL, the first electrode pattern NI, and the second electrode pattern PI may be formed of, for example, a single layer of tungsten. Other configurations may be the same/similar to those described above.

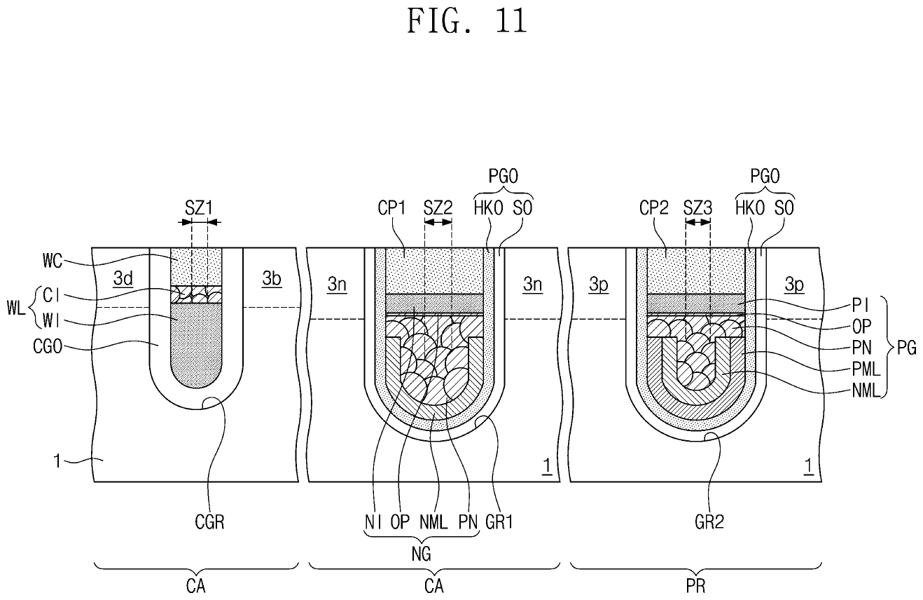

FIG. 11 is cross-sectional views of a semiconductor device according to embodiments of the present disclosure.

Referring to FIG. 11, in a semiconductor device according to the present embodiment, a third cell electrode pattern CI of a word line WL, a polysilicon pattern PN of a first gate electrode NG, and a polysilicon pattern PN of a second gate electrode PG may include silicon grains of different sizes. For example, silicon grains of the third cell electrode pattern CI of the word line WL may have a first average size SZ1. Silicon grains of the polysilicon pattern PN of the first gate electrode NG may have a second average size SZ2. Silicon grains of the polysilicon pattern PN of the second gate electrode PG may have a third average size SZ3. For example, the third average size SZ3 may be larger than the first average size SZ1 and smaller than the second average size SZ2. Other configurations may be the same/similar to those described in FIG. 10.

In the semiconductor device according to the present disclosure, since the gate electrodes of the NMOS and PMOS regions are all sunk into the substrate like the word line of the cell region, the channel length of the NMOS transistor and the PMOS transistor is increased, thereby minimizing the short channel effect. In addition, by eliminating the step difference between the cell region and the peripheral region, it is possible to prevent process defects and simplify the process in a subsequent manufacturing process.

In addition, in a structure in which a gate electrode is recessed, a P-type conductive pattern is used as a P-type conductive pattern to adjust the work function to improve the performance of a PMOS transistor in a structure in which a gate electrode is recessed. It may be formed foamy. In addition, molybdenum titanium nitride (MoTiN) or molybdenum silicon nitride (MoSiN) has a high work function and excellent thermal stability, so that the threshold voltage of a PMOS transistor is constant even at a high temperature, so that the operation reliability of a semiconductor device may be improved.

While embodiments are described above, a person skilled in the art may understand that many modifications and variations are made without departing from the spirit and scope of the present disclosure defined in the following claims. Accordingly, the example embodiments of the present disclosure should be considered in all respects as illustrative and not restrictive, with the spirit and scope of the present disclosure being indicated by the appended claims.

What is claimed is:

1. A semiconductor device, comprising:
a substrate including an NMOS region and a PMOS region;
a first gate electrode in the substrate in the NMOS region; and
a second gate electrode in the substrate in the PMOS region,
wherein the first gate electrode includes a first electrode pattern,
wherein the second gate electrode includes a second electrode pattern,
wherein the first gate electrode further includes a first N-type conductive pattern between the first electrode pattern and the substrate,
wherein the second gate electrode further includes a P-type conductive pattern between the second electrode pattern and the substrate, and
wherein the P-type conductive pattern includes molybdenum titanium nitride (MoTiN) or molybdenum silicon nitride (MoSiN).

2. The semiconductor device of claim 1, wherein a content of titanium or silicon in the P-type conductive pattern is about 1.0 to 50.0 atomic percent (at. %).

3. The semiconductor device of claim 1, wherein the second gate electrode further includes a second N-type conductive pattern between the P-type conductive pattern and the second electrode pattern.

4. The semiconductor device of claim 1, wherein the substrate further includes a cell region, and
wherein the semiconductor device further includes:
a word line in the substrate in the cell region; and
a cell gate insulating layer between the word line and the substrate.

5. The semiconductor device of claim 4, wherein a width of the word line, in a direction parallel to an upper surface of the substrate, is smaller than a width of the first electrode pattern or a width of the second electrode pattern in the direction.

6. The semiconductor device of claim 4, wherein the first N-type conductive pattern includes a first sub-N-type conductive pattern and a second sub-N-type conductive pattern, the first sub-N-type conductive pattern is between the substrate and the second sub-N-type conductive pattern,
wherein the word line includes a first cell electrode pattern and a second cell electrode pattern sequentially stacked relative to one another,
wherein the second sub-N-type conductive pattern and the first cell electrode pattern include titanium nitride, and
wherein the second cell electrode pattern includes a material the same as materials of the first electrode pattern and the second electrode pattern.

7. The semiconductor device of claim 4, wherein the first N-type conductive pattern includes a first sub-N-type conductive pattern and a second sub-N-type conductive pattern, the first sub-N-type conductive pattern is between the substrate and the second sub-N-type conductive pattern,
wherein the word line includes a first cell electrode pattern and a second cell electrode pattern sequentially stacked relative to one another,
wherein the first gate electrode further includes a polysilicon pattern and a metal-containing pattern between the first electrode pattern and the first N-type conductive pattern,
wherein the first cell electrode pattern and the first electrode pattern include tungsten, and
wherein the second cell electrode pattern and the polysilicon pattern include polysilicon comprising one or more types of impurities.

8. The semiconductor device of claim 1, wherein the first electrode pattern has a width, in a direction parallel to an upper surface of the substrate, larger than a width of the second electrode pattern in the direction.

9. A semiconductor device, comprising:
a substrate including an NMOS region and a PMOS region, including a first groove in the substrate in the NMOS region and a second groove in the substrate in the PMOS region;
a first gate insulating layer and a first N-type conductive pattern sequentially stacked and covering an inner wall of the first groove;
a first electrode pattern in the first groove;
a second gate insulating layer, a P-type conductive pattern, and a second N-type conductive pattern sequentially stacked and covering an inner wall of the second groove; and
a second electrode pattern in the second groove,
wherein the P-type conductive pattern has a work function of about 5.0 electron-volts (eV) to 5.5 eV and the P-type conductive pattern includes titanium and/or silicon, and
wherein a content of titanium and/or silicon is about 1.0 to 50.0 atomic percent (at. %).

10. The semiconductor device of claim 9, wherein the P-type conductive pattern includes molybdenum titanium nitride (MoTiN) or molybdenum silicon nitride (MoSiN).

11. The semiconductor device of claim 9, wherein the substrate further includes a cell region, and
wherein the semiconductor device further includes:
a word line in the substrate in the cell region; and
a cell gate insulating layer between the word line and the substrate.

12. The semiconductor device of claim 11, wherein a first width of the word line is smaller than a second width of the first electrode pattern or a third width of the second electrode pattern, the first, second and third widths being in a direction parallel to an upper surface of the substrate.

13. The semiconductor device of claim 11 wherein the first N-type conductive pattern includes a first sub-N-type conductive pattern and a second sub-N-type conductive pattern, the first sub-N-type conductive pattern is between the substrate and the second sub-N-type conductive pattern,
wherein the word line includes a first cell electrode pattern and a second cell electrode pattern sequentially stacked relative to one another,
wherein the second sub-N-type conductive pattern and the first cell electrode pattern include titanium nitride, and
wherein the second cell electrode pattern includes a material the same as materials of the first electrode pattern and the second electrode pattern.

14. The semiconductor device of claim 11, wherein the first N-type conductive pattern includes a first sub-N-type conductive pattern and a second sub-N-type conductive pattern, the first sub-N-type conductive pattern is between the substrate and the second sub-N-type conductive pattern,
wherein the word line includes a first cell electrode pattern and a second cell electrode pattern sequentially stacked relative to one another,
wherein the semiconductor device further includes a polysilicon pattern and a metal-containing pattern sequentially stacked relative to one another and between the first electrode pattern and the first N-type conductive pattern in the first groove,
wherein the first cell electrode pattern and the first electrode pattern include tungsten, and
wherein the second cell electrode pattern and the polysilicon pattern include polysilicon comprising one or more types of impurities.

15. The semiconductor device of claim 9, wherein the first electrode pattern has a first width, in a direction parallel to an upper surface of the substrate, that is larger than a second width of the second electrode pattern.

16. A semiconductor device, comprising:
a substrate including a cell region and a peripheral region, the peripheral region including an NMOS region and a PMOS region, and including a cell groove in the substrate in the cell region, a first groove in the substrate in the NMOS region, and a second groove in the substrate in the PMOS region;
a word line in the cell groove;
a first impurity region in the substrate adjacent a first side of the word line;
a second impurity region in the substrate adjacent a second side of the word line laterally opposite the first side;
a bit line connected to the first impurity region and crossing over the word line;
a storage node contact connected to the second impurity region;
a data storage pattern on the storage node contact;
a first gate insulating layer and a first N-type conductive pattern sequentially stacked relative to one another and covering an inner wall of the first groove;
a first electrode pattern at least partially filling the first groove;
a second gate insulating layer, a P-type conductive pattern, and a second N-type conductive pattern sequentially stacked and covering an inner wall of the second groove; and
a second electrode pattern at least partially filling the second groove,
wherein the P-type conductive pattern includes molybdenum titanium nitride (MoTiN) or molybdenum silicon nitride (MoSiN), and
wherein a content of titanium or silicon in the P-type conductive pattern is about 1.0 to 50.0 atomic percent (at. %).

17. The semiconductor device of claim 16, wherein a first width of the word line is smaller than a second width of the first electrode pattern or a third width of the second electrode pattern, the first, second and third widths being in a direction parallel to an upper surface of the substrate.

18. The semiconductor device of claim 16, wherein the first N-type conductive pattern includes a first sub-N-type conductive pattern and a second sub-N-type conductive pattern, the first sub-N-type conductive pattern is between the substrate and the second sub-N-type conductive pattern,
wherein the word line includes a first cell electrode pattern and a second cell electrode pattern sequentially stacked relative to one another,
wherein the second sub-N-type conductive pattern and the first cell electrode pattern include titanium nitride, and
wherein the second cell electrode pattern includes a material the same as materials of the first electrode pattern and the second electrode pattern.

19. The semiconductor device of claim 16, wherein the first N-type conductive pattern includes a first sub-N-type conductive pattern and a second sub-N-type conductive pattern, the first sub-N-type conductive pattern is between the substrate and the second sub-N-type conductive pattern,
wherein the word line includes a first cell electrode pattern and a second cell electrode pattern sequentially stacked relative to one another,
wherein the semiconductor device further includes a polysilicon pattern and a metal-containing pattern sequentially stacked and between the first electrode pattern and the first N-type conductive pattern in the first groove,
wherein the first cell electrode pattern and the first electrode pattern include tungsten, and
wherein the second cell electrode pattern and the polysilicon pattern include polysilicon comprising one or more types of impurities.

20. The semiconductor device of claim 16, wherein the first electrode pattern has a first width larger than a second width of the second electrode pattern.
